(19) United States
(12) Patent Application Publication
(10) Pub. No.: US 2014/0003630 A1
(43) Pub. Date: Jan. 2, 2014

(54) AUDIO PROCESSOR AND COMPUTER PROGRAM PRODUCT

(71) Applicant: KABUSHIKI KAISHA TOSHIBA, Tokyo (JP)

(72) Inventors: Takenhiko Demiya, Ome-shi (JP); Masataka Osada, Kawasaki-shi (JP); Yusaku Kikugawa, Ome-shi (JP)

(73) Assignee: Kabushiki Kaisha Toshiba, Tokyo (JP)

(21) Appl. No.: 13/766,398

(22) Filed: Feb. 13, 2013

(30) Foreign Application Priority Data
Jun. 27, 2012 (JP) 2012-144384

(51) Int. Cl. H03G 3/20

(52) U.S. Cl. CPC H03G 3/20
USPC 381/107

(57) ABSTRACT

According to one embodiment, an audio processor includes a detector and a controller. The detector is configured to detect a first interval during which a state in which a reproduced sound by an audio signal is assumed to be silent continues for at least a first time. The controller is configured to change, during the first interval, an output level of the audio signal.

### CROSS-REFERENCE TO RELATED APPLICATIONS

This application is based upon and claims the benefit of priority from Japanese Patent Application No. 2012-144384, filed Jun. 27, 2012, the entire contents of which are incorporated herein by reference.

### FIELD

Embodiments described herein relate generally to an audio processor and a computer program product.

### BACKGROUND

Recently, an audio reproducer designed for mobile use and driven by a rechargeable battery has been widely used. In the audio reproducer, a method of automatically controlling a reproduced sound can be used for reducing power consumption in order to prolong the driving time by the battery. For example, when the volume of the reproduced sound reaches a predetermined value, the volume is controlled to be gradually lowered.

In the conventional technology, if the volume of the reproduced sound is gradually changed while a user is listening to the sound, the user notices the change in the sound volume and this might make the user feel uncomfortable.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary block diagram of an audio processor according to an embodiment;

FIGS. 2A to 2C are exemplary diagrams of relationships of output signal power and a threshold Pₜₕ when effect controlling and gain controlling are performed, in the embodiment;

FIG. 3 is an exemplary diagram illustrating correction control in the embodiment;

FIG. 4 is an exemplary diagram schematically illustrating detection of a silence interval using a first method in the embodiment;

FIG. 5 is an exemplary diagram of a gap a human can notice as a silence for each frequency band, in the embodiment;

FIG. 6 is an exemplary diagram schematically illustrating detection of the silence interval using a second method in the embodiment;

FIGS. 7A to 7D are exemplary diagrams schematically illustrating detection of the silence interval using a third method in the embodiment;

FIG. 8 is an exemplary flowchart of a processing in a correction module in the embodiment; and

FIG. 9 is an exemplary block diagram of a structure of an audio reproducer to which the embodiment can be applied.

### DETAILED DESCRIPTION

In general, according to one embodiment, an audio processor comprises: a detector; and a controller. The detector is configured to detect a first interval during which a state in which a reproduced sound by an audio signal is assumed to be silent continues for at least a first time. The controller is configured to change, during the first interval, an output level of the audio signal.

Hereinafter, an audio processor in the embodiment will be described. In the embodiment, an interval in an audio signal during which it is assumed that no sound present. If the detected interval continues for a period of equal to or more than a predetermined length, an output level of the audio signal in the interval is changed. For example, by changing volume of the interval during which it is assumed that no sound present, it can be avoided that the user notices the change in sound volume and is made to feel uncomfortable.

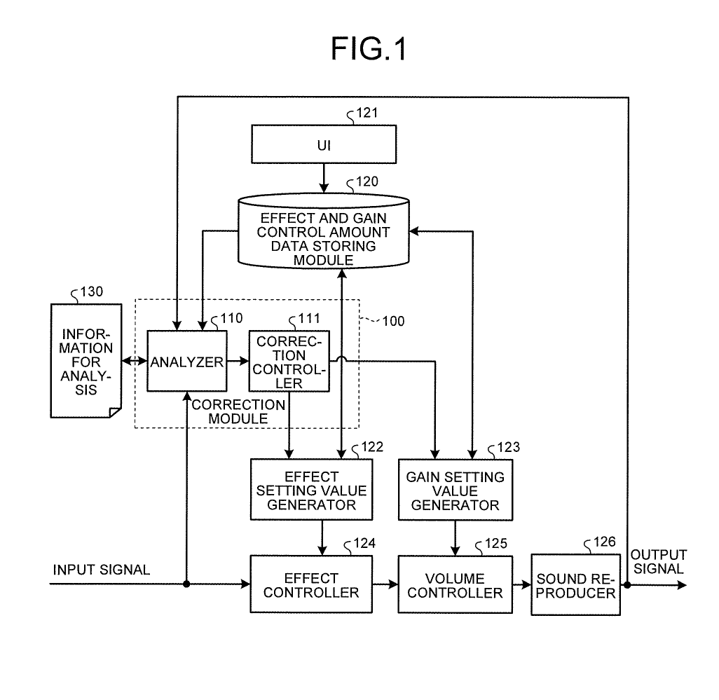

FIG. 1 is a block diagram of the audio processor according to the embodiment. The audio processor comprises a correction module 100, an effect and gain control amount data storing module 120, a user interface (UI) 121, an effect setting value generator 122, again setting value generator 123, an effect controller 124, a volume controller 125, and a sound reproducer 126. The correction module 100 comprises an analyzer 110 and a correction controller 111. The analysis result of the analyzer 110 is maintained and accumulated as information 130 for analysis.

A digital audio signal is input as an input signal to an audio reproducer 1. The digital audio signal that has been input is provided to the correction module 100 and also to the effect controller 124. The effect controller 124 performs effect processing in accordance with an effect setting value provided from the effect setting value generator 122 on the digital audio signal, and provides a sound effect in accordance with the effect processing on the digital audio signal. An example of the effect processing performed by the effect controller 124 is equalizer processing that adjusts gain of a predetermined frequency band or reverberation processing that provides a reproduced sound with a reverberation effect.

The digital audio signal that has been output from the effect controller 124 is provided to the volume controller 125. The volume controller 125 controls the gain for the digital audio signal provided in accordance with the gain setting value provided from the gain setting value generator 123. If the gain is 0, the level of the digital audio signal shall be 0 to make a silent state. If the gain is 1, the level of the digital audio signal provided is output without change.

The digital audio signal output from the volume controller 125 is output through the sound reproducer 126.

The effect and gain control amount data storing module 120 stores therein the effect setting value for use in the effect controller 124 or the gain setting value for use in the volume controller 125, for example. A plurality of types of effect setting values and gain setting values are generated in advance, for example, and stored in the effect and gain control amount data storing module 120. The effect setting value and the gain setting value set in accordance with an input by a user via the user interface 121 is stored in the effect and gain control amount data storing module 120. In addition, the effect setting value and the gain setting value generated in the effect setting value generator 122 or the gain setting value generator 123 both described later, are stored in the effect and gain control amount data storing module 120.

In view of a case when, for example, the audio processor operates so as to increase its battery driving time as much as possible, the information 130 for analysis comprises information on a remaining amount of battery power and a threshold of an output signal level of the sound reproducer 126, in association with each other. Here, the threshold of the output signal level corresponds to a power consumption determined permissible for the remaining amount of battery power. The information 130 for analysis may further comprise a cumulative number of times and a cumulative time in which the output signal level exceeds the threshold.

In the correction module 100, information representing the remaining amount of battery power is provided from a power source (not illustrated) and information representing the level of the output signal from the sound reproducer 126 to the analyzer 110. The analyzer 110 analyzes these pieces of information to obtain the number of times and the time in which the output signal level exceeds the threshold described above. The analyzer accumulates the information on the number of times and the time in which the output signal level exceeds the threshold that has been obtained onto the information 130 for analysis.

In addition, the digital audio signal received as an input signal is provided to the analyzer 110. The analyzer 110 analyzes the input digital audio signal to obtain the signal level of the digital audio signal. The analyzer 110 analyzes the input digital audio signal for each frequency band. More specifically, the analyzer 110 performs time to frequency conversion on the input digital audio signal. For the time to frequency conversion, the Fast Fourier Transform (FFT) can be used, for example. However, the embodiment is not limited to this example. The modified discrete cosine transform (MDCT) may also be used to perform the time to frequency conversion.

In the FFT, the window length is set to 2048 samples (1024 is obtained as FFT bins), while the sampling rate of the input digital audio signal is set to 48 kHz, for example. In this example, the input digital audio signal converted using the time to frequency conversion is calculated as the signal power for each frequency band using the following Equation (1).

sig_spec_power[i]=sig_spec_{—}r[i]²−sig_spec_{—}i[i]² (1)

In Equation (1), each variable is defined as follows.
i: an index of the frequency sample (where 0≦i1023)
sig_spec_r[i]: a real part of each frequency sample
sig_spec_i[i]: an imaginary part of each frequency sample
sig_spec_power[i]: signal power of each frequency sample

The analyzer 110 reads out the effect setting value and the gain setting value that are going to be added to the digital audio signal received from the effect and gain control amount data storing module 120. Subsequently, as represented in the following Equation (2), the analyzer 110 adds the signal power effected_gain[i] to be increased via effect controlling in accordance with the read out effect setting value and the signal power added_gain[i] to be increased via gain controlling in accordance with the read out gain setting value to the signal power for each frequency band sig_spec_power[i] obtained using Equation (1). As a result, the signal power of the output signal sig_proc_power[i] of when the effect controlling by the effect setting value and the gain controlling by the gain setting value are performed to the input digital audio signal can be estimated.

sig_proc_power[i]=sig_spec_power[i]+effected_gain[i]+added_gain[i] (2)

After that, the analyzer 110 searches the estimated maximum value of the signal power on which the processing by the effect controller 124 and the volume controller 125 are performed, based on the signal power of the output signal sig_proc_power[i] obtained by Equation (2) described above. The analyzer 110 also obtains, using the following Equation (3), the frequency sig_max_freq (Hz) at which the maximum value of the signal power sig_max_power is acquired. Here, the index of the frequency sample corresponding to the maximum value of the signal power that has been searched is set as the value, sig_max_index.

sig_max_freq=sig_max_index×1024/24,000 (3)

Each result of analysis by the analyzer 110 is provided to the correction controller 111. The correction controller 111 detects the interval (referred to as a silence interval or a first interval) during which a state in which the reproduced sound by the input digital audio signal is silent or assumed to be silent continues for at least a predetermined time (first time) based on the analysis result provided. Then, the correction controller 111 determines each correction value for effect controlling or volume controlling to reduce the signal power of the output signal in the silence interval. Each correction value determined for effect controlling or volume controlling is provided to the effect setting value generator 122 or the gain setting value generator 123.

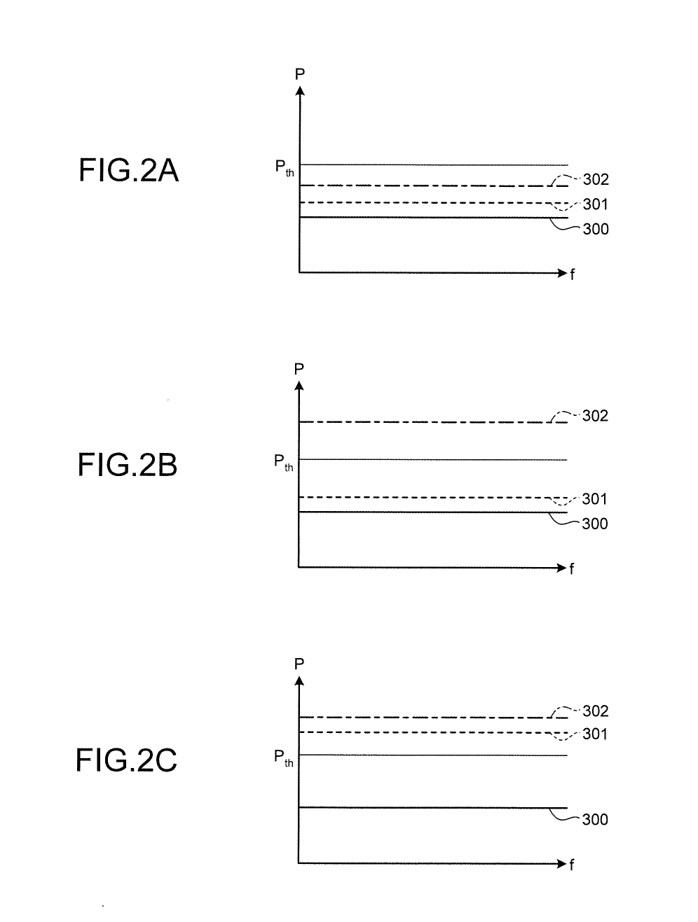

Determination of the correction values in the correction controller 111 will now be described in detail. FIGS. 2A to 2C illustrate relationships between the signal power of the output signal and a threshold Pₜₕ when effect controlling and gain controlling in the embodiment are performed on the input digital audio signal. In FIGS. 2A to 2C, the vertical axis represents a signal power P, while the horizontal axis represents a frequency f. In the following description, the signal power P has a characteristic of flatness for each frequency f.

In FIGS. 2A to 2C, each threshold Pₜₕ is a value determined for the output signal power so that the power consumption is equal to or less than a predetermined value, for example. The signal power of an input digital audio signal 300 is lower than the threshold Pₜₕ.

A first output signal 301 in which gain controlling is performed on the input digital audio signal 300 and a second output signal 302 in which gain controlling and effect controlling are performed on the input digital audio signal are compared with the threshold Pₜₕ.

FIG. 2A illustrates an example in which no correction is required for effect controlling in the effect controller 124 and gain controlling in the volume controller 125 (referred to as a first case). In the first case, the output signal power of the first output signal 301 and the output signal power of the second output signal 302 are both lower than the threshold Pₜₕ, so that no correction is required for effect controlling in the effect controller 124 and gain controlling in the volume controller 125.

FIG. 2B illustrates an example in which a correction is required for effect controlling (referred to as a second case). In the second case, as represented in Equation (4), the output signal power of the first output signal 301 on which only gain controlling is performed is lower than the threshold Pₜₕ.

sig_spec_power[sig_max_index]+added_gain[i]<Pₜₕ (4)

In the second case, the output signal power of the second output signal 302 on which gain controlling and effect controlling are performed is higher than the threshold Pₜₕ. Therefore, by suppressing effect processing by the effect controller 124, the output signal power of the second output signal 302 is suppressed so as to be lower than the threshold Pₜₕ, as represented in the following Equation (5).

sig_max_power<Pₜₕ (5)

In other words, in the second case, the correction controller 111 generates the correction value for suppressing the effect controlling by the effect controller 124. More specifically, the correction controller 111 generates a correction value for the effect controlling so that the maximum value of the output signal power sig_max_power becomes less than or equal to Pₜₕ. Here, the maximum value of the output signal power sig_max_power is obtained by adding the signal power effected_gain[i] which is an amount increased by the effect controlling performed by the effect controller 124, to the signal power obtained by adding the signal power sig_spec_power[i] of the input digital audio signal to the signal power added_gain[i] which is an amount increased by the gain controlling performed by the volume controller 125.

FIG. 2C illustrates an example in which correction is necessary for both effect controlling in the effect controller 124 and gain controlling in the volume controller 125 (referred to as a third case). In the third case, as represented in Equations (6) and (7) below, the output signal power of the first output signal 301 on which only gain controlling is performed is equal to or more than the threshold Pₜₕ, and, the output signal power of the second output signal 302 on which gain controlling and effect processing are performed is equal to or more than the threshold Pₜₕ.

sig_spec_power[sig_max_index]+added_gain[i]≧Pₜₕ (6)

sig_spec_power[sig_max_index]+effected_gain[i]+added_gain[i]≧Pₜₕ (7)

In other words, in the third case, even if the effect processing by the effect controller 124 is removed, the output signal power still exceeds the threshold Pₜₕ due to the gain added in accordance with the gain controlling by the volume controller 125. Therefore, in the third case, the correction controller 111 suppresses the effect processing performed by the effect controller 124 and the gain controlling performed by the volume controller 125, as represented in Equation (5) described above, thereby reducing the output signal power of the second output signal 302 to be equal to or lower than the threshold Pₜₕ.

For example, the correction controller 111 generates the correction values that instruct suppression of the effect processing by the effect controller 124 and suppression of the gain by the volume controller 125. Specifically, the correction controller 111 generates a correction value for the effect controller 124 and a correction value for the volume controller 125 so that the signal power as a result of the suppression of the effect processing and the suppression of the gain is equal to or less than the threshold Pₜₕ.

However, the embodiment is not limited thereto. The correction controller 111 may generate the correction value that suppresses the effect processing for the effect controller 124 and generate a correction value that does not perform suppression of gain controlling for the volume controller 125. The correction controller 111 may also generate the correction value that instructs the effect controller 124 not to perform effect processing and may perform gain controlling only.

In the second and third cases, to satisfy Equation (5), an excessive amount “error” representing a signal power to be reduced through effect controlling and gain controlling is obtained using the following Equation (8).

error=sig_max_power−Pₜₕ (8)

Which of the effect controlling or gain controlling is used to correct the excessive amount “error” represented in Equation (8) can be determined by placing priority on either the sound quality or power consumption reduction, for example. Here, it can be considered that, for example, if the priority of the sound quality is higher, the entire excessive amount “error” is corrected through gain controlling. On the other hand, if the priority of the power consumption reduction is higher, the excessive amount “error” is corrected by removing the effect and the lack of signal power is compensated through gain controlling.

Transition of correction level when the excessive amount “error” is corrected will now be described. Correction is performed using a period T, which is approximately a period during which a human can hardly recognize the correction acoustically. The unit of the period T is not limited. For example, a system clock or the sampling rate of the digital audio signal can be used for the unit of the period T. A frame, which is a unit of processing of the digital audio signal can also be used for the unit of the period T. Although varied depending on the amount of the signal power to be reduced (correction amount), generally, a relatively long time e.g., 10 seconds or longer is necessary for the period T.

In the embodiment, during the period T, an interval during which a state in which the reproduced sound by the input digital audio signal is assumed to be silent continues for at least a predetermined time (referred to as the silence interval) is detected. Within the silence interval, correction to reduce a predetermined output signal power out of the excessive amount “error” is performed. Processing of this correction is repeated at least within the period T described above so that the total amount of correction in a plurality of times equals to the excessive amount “error”.

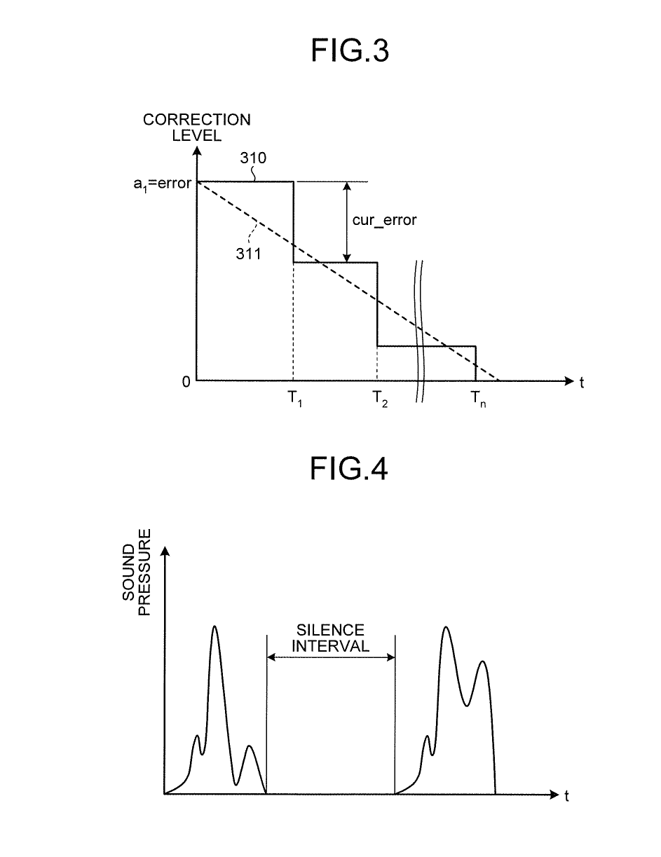

FIG. 3 illustrates an example of correction control in the embodiment. In FIG. 3, the vertical axis represents a correction level a of the excessive amount “error”, while the horizontal axis represents time. A control line 310 represents an example of a change in the correction level a due to the correction control in the embodiment.

For example, the analyzer 110 analyzes the input digital audio signal to obtain a time T₀ at which the maximum value of the signal power sig_max_power exceeds the threshold Pₜₕ. The time T₀ may be an absolute time or a relative time within the input digital audio signal. Then, the analyzer 110 obtains the number of silence intervals n generated until the predetermined time T elapses from the time T₀ obtained. The value obtained by dividing the excessive amount “error” by the number of silence intervals n shall be cut_error, a correction amount at one time.

The correction controller 111 generates the correction value so that the output signal power is reduced in increments of the correction amount cur_error at the number of n time points T₁, T₂, . . . , Tₙ in the silence interval after the time T₀, as illustrated in FIG. 3. That is to say, the correction amount cur_error at an arbitrary time point t from the time T₀ to the time Tₙ is given from the correction level aₘ (m is an integer; 1≦m≦n) representing a necessary correction amount according to Equation (9).

$$\begin{matrix}cur\_error = \{ \begin{matrix}{a}_{1} = error & ( {T}_{0} \leq t < {T}_{1} ) \\ {a}_{2} & ( {T}_{1} \leq t < {T}_{2} ) \\ ⋮ & \\ {a}_{i} & ( {T}_{i - 1} \leq t < {T}_{i} ) \\ ⋮ & \\ {a}_{n} = 0 & ( {T}_{n - 1} \leq t < {T}_{n} )\end{matrix} \\ T = \{ {T}_{0} = 0 , {T}_{1} , {T}_{2} , … , {T}_{i} , … , {T}_{n} \}\end{matrix} \qquad ( 9 )$$

From the time T₀ to a first time point T₁ in the silence interval, correction is not performed so the correction level a₁ is equal to the excessive amount “error”. At the time point T₁, correction by the correction amount cur_error is performed so that the correction level a₂ becomes the excessive amount “error” minus the correction amount cur_error for one time. The output signal power at the time point T₁ becomes the value obtained by reducing the output signal power at the time point T₀ by the correction amount cur_error.

From the time point T₁ to a second time point T₂ in the silence interval, the correction level does not change from the correction level a₂ according to Equation (9). Therefore, the output signal power also maintains the value at the time point T₁. At the time point T₂, correction by the correction amount cur_error is performed so that the correction level a₃ becomes the excessive amount “error” minus the correction amount cur_error for two times. The output signal power at the time point T₂ becomes the value obtained by further reducing the output signal power at the time point T₁ by the correction amount cur_error.

Subsequently, in the same manner, correction by the correction amount cur_error is repeated for each silence interval to reduce the excessive amount “error”, thereby making the output signal power equal to or less than the threshold Pₜₕ.

It is said that according to the characteristic of human auditory sense, a human can hardly notice a change in output signal power that occurs in the silence interval. In the embodiment, by utilizing this characteristic of human auditory sense, the output signal power is reduced in a step-by-step manner in each silence interval, whereby correction process of the sound effect and volume control for the targeted output signal power can be converged in such a manner that a human can hardly notice the process.

In FIG. 3, a control line 311 illustrates a change in the correction level using correction control of a conventional technique. Conventionally, for the time T from the time point T₀, the correction level is continuously changed as illustrated in the figure. In this case, a human can notice the correction process of the sound effect or volume in the interval other than the silence interval, whereby the user feels uncomfortable.

In the description above, correction by the excessive amount “error” is performed for the time T. However, the embodiment is not limited to this example. The correction by the excessive amount “error” may be performed for at least the time T.

A first method for detecting the silence interval described above will now be described. FIG. 4 schematically illustrates detection of the silence interval using a first method in the embodiment. In FIG. 4, the vertical axis represents a sound pressure level, while the horizontal axis represents time. The sound pressure level is the value when a signal that has been output from the sound reproducer 126, for example, is reproduced on a speaker, for example, which corresponds to the output signal power. Hereinafter, the sound pressure level is explained as the output signal power.

In the first method, as illustrated in FIG. 4, a period in which the output signal power is 0 is detected as the silence interval. In this method, a period in which the signal level of the input digital audio signal is 0 may be detected as the interval. The output signal power is not limited to be completely 0. A period in which the output signal power is equal to or less than the threshold may be detected as the interval. The threshold of the output signal power may be such a value at which a human can hardly hear when a sound is reproduced using a possible audio reproducing unit (e.g., a speaker). Furthermore, for example, it could be a period between phonemes during which noise suppression is performed to reduce noise components in the input digital audio signal.

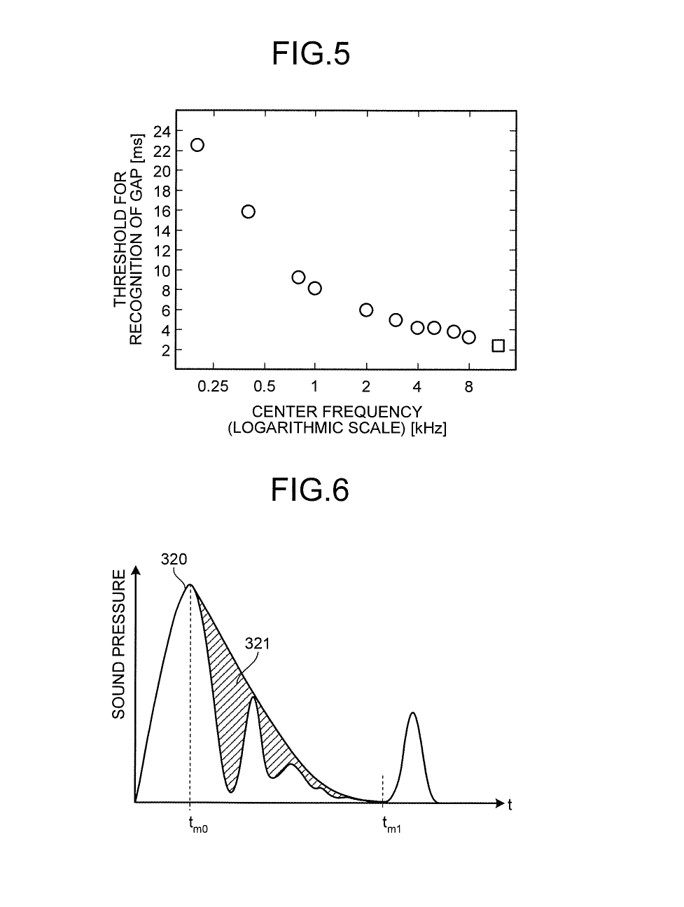

The shortest time a human can recognize as silence (referred to as a gap) depends on frequency. FIG. 5 illustrates a gap a human can recognize as silence for each frequency band. The band of noise in FIG. 5 is half of the center frequency. As illustrated here, the gap becomes shorter when the center frequency becomes higher, and the gap becomes longer when the center frequency becomes lower. For example, when the lower limit on the low-frequency side of an effective frequency band of a speaker or other audio output device that is assumed to be used is 100 Hz, then, with reference to FIG. 5, a human can recognize from the speaker that an interval of silence exists in the output if a gap of at least nearly 23 ms exists.

A second method for detecting the silence interval described above will now be described. FIG. 6 schematically illustrates detection of the silence interval using the second method in the embodiment. In FIG. 6, the vertical axis represents a sound pressure level, while the horizontal axis represents time.

In the second method, the silence interval is detected using a temporal masking of sound. The temporal masking of sound refers to the phenomenon in which, when a loud sound suddenly occurs, sounds around the loud sound cannot be heard. The phenomenon in which the sound prior to the loud sound causing temporal masking cannot be heard refers to backward masking, while the phenomenon in which the sound subsequent to the loud sound causing temporal masking cannot be heard refers to forward masking. In the second method, the phenomenon that the sound subsequent to the sound causing temporal masking cannot be heard is utilized, and therefore, the temporal masking refers to forward masking hereinafter.

For example, as illustrated in FIG. 6, if a loud sound 320 occurs at a time Tₘ₀, the sound reproduced from immediately after the time point Tₘ₀ to the time point Tₘ₁ cannot be heard due to a temporal masking 321 caused by the sound 320. That is to say, from immediately after the time point Tₘ₀ to the time point Tₘ₁ any reproduced sound other than the sound 320 cannot be heard. The other reproduced sounds are thus deemed to be silent. The reproduction of the sound 320 is completed immediately after the time point Tₘ₀, and the period from immediately after the time point Tₘ₀ to the time point Tₘ₁ may be deemed to be silent.

In the second method, the period of temporal masking is assumed to be the silence interval to perform gain controlling to reduce the signal power of the input digital audio signal in the volume controller 125. Accordingly, the reproduced sound by the input digital audio signal during the period from immediately after the sound 320 that causes the temporal masking is generated (the time point Tₘ₀) to the time point Tₘ₁ at which temporal masking ends cannot be heard practically. Therefore, even if the gain controlling or the effect controlling is changed during the period of temporal masking, a human can hardly notice the change.

When the period from the time point tₘ₀ to the time point tₘ₁ during which other sounds cannot be heard due to temporal masking is detected as the silence interval, the aforementioned frequency gap dependency can be used. In particular, the period can be detected as the silence interval if the temporal masking occurs for a period longer than the gap corresponding to the assumed frequency.

The sound pressure level of the sound that cannot be heard due to temporal masking decreases in an exponential manner as time passes from the time Tₘ₀ at which temporal masking occurs. Using the sound pressure level of the sound that cannot be heard due to temporal masking as a threshold, the silence interval can be detected. Temporal masking has two types: forward masking in which the sound subsequent to the sound 320 is masked; and backward masking in which the sound prior to the sound 320 is masked, as described above. Only forward masking is adopted here.

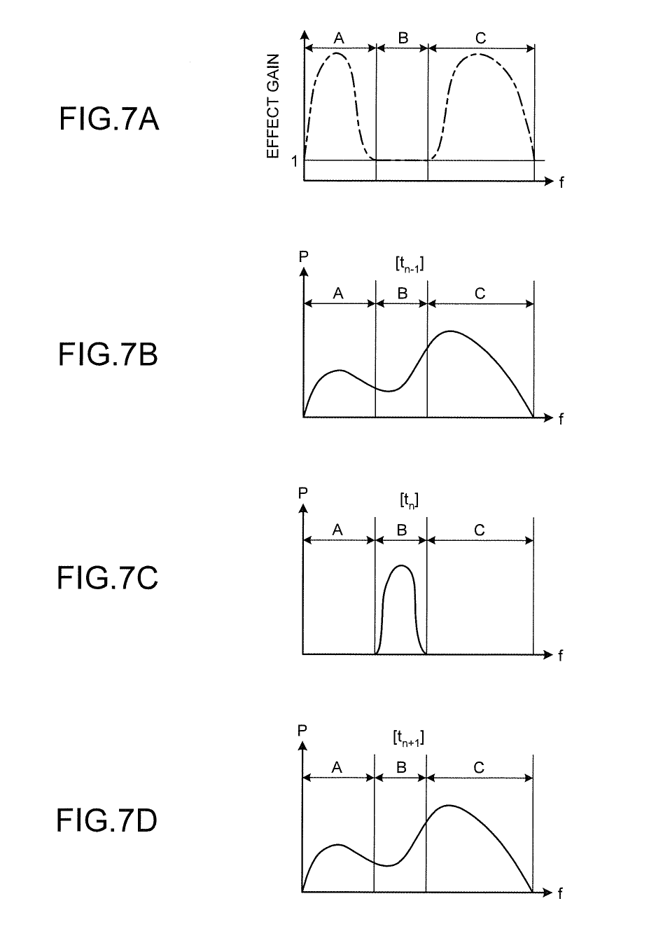

A third method for detecting the silence interval described above will now be described. FIGS. 7A to 7D schematically illustrate detection of the silence interval using the third method in the embodiment. The third method is an example of detecting the silence interval for each frequency band.

As illustrated in FIG. 7A, an example in which effect controlling is performed for each frequency band is considered. In FIG. 7A, the vertical axis represents the increased amount of gain due to the effect, while the horizontal axis represents the frequency. Here, it is considered for example that effect controlling in which gains of a frequency band A on the low-frequency side and a frequency band C on the high-frequency side are increased through equalizer processing as the effect controlling while gain of a frequency band B on the middle-frequency side is not changed.

FIGS. 7B to 7D exemplify changes along time of the input digital audio signal. In FIGS. 7B to 7D, the vertical axis represents the signal power, while the horizontal axis represents the frequency. FIGS. 7B to 7D respectively exemplify the input digital audio signal at the time point Tₙ₋₁, the time point Tₙ, and the time point Tₙ₊₁, in time sequence. On these input digital audio signal at each time point, the effect controlling illustrated in FIG. 7A is performed.

At the time point Tₙ₋₁ illustrated in FIG. 7B, the signal power of the input digital audio signal in the frequency bands A and C is not 0. The signal level in the frequency bands A and C is thus increased through effect controlling in accordance with the gain in the frequency bands A and C illustrated in FIG. 7A.

At the time point Tₙ illustrated in FIG. 7C, the signal power of the input digital audio signal in the frequency bands A and C is equal to or less than the threshold (e.g., 0). Therefore, the time point Tₙ is detected to comprise the silence interval in the frequency bands A and C. If the state of the time point Tₙ continues for at least a predetermined time, correction is performed to suppress the effect controlling illustrated in FIG. 7A.

At the time point Tₙ₊₁ illustrated in FIG. 7D, the signal power of the input digital audio signal in the frequency bands A and C is no longer 0. At the time point Tₙ₊₁, effect controlling that has been suppressed at the time point Tₙ described above is performed, so the output signal power at the time point Tₙ₊₁ is lower than that at the time point Tₙ₋₁ illustrated in FIG. 7B.

The first, second, and third methods are not limited to be performed individually. Two or three methods may be combined to be performed.

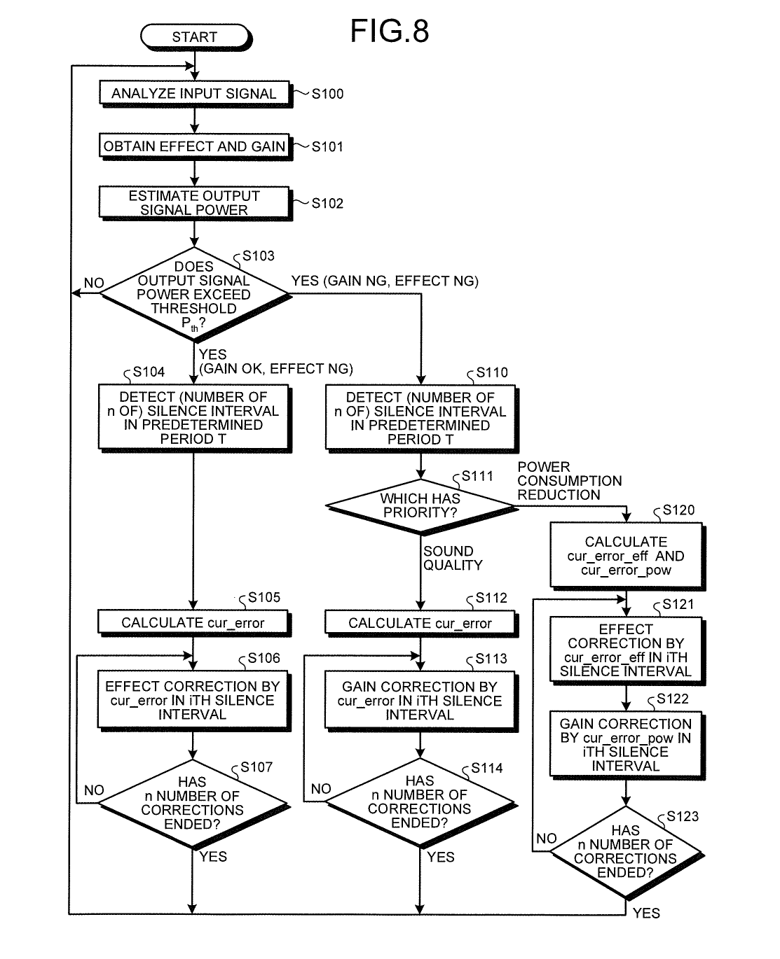

A processing in the correction module 100 in the embodiment will now be described with reference to the flowchart illustrated in FIG. 8. In the correction module 100, the analyzer 110 analyzes the input digital audio signal that is an input signal, at S100. For example, the input digital audio signal is stored for each predetermined amount (for each predetermined reproduction time) in a buffer memory (not illustrated). The analyzer 110 performs FFT on the predetermined amount of the input digital audio signal stored in the buffer memory to perform the time to frequency conversion. However, the embodiment is not limited to this example. If information on the frequency is not required, for example, the analyzer 110 may calculate root means square (RMS) values of the input digital audio signal.

At the subsequent S101, the analyzer 110 obtains the effect setting value and the gain setting value that are to be added to the input digital audio signal from the effect and gain control amount data storing module 120. At the subsequent S102, the analyzer 110 estimates the output signal power based on the analysis result of the input digital audio signal at S100 and the effect setting value and the gain setting value obtained at S101 in the manner described using Equation (1) to Equation (3). The analysis result by the analyzer 110 is transferred to the correction controller 111.

At the subsequent S103, the correction controller 111 determines whether the output signal power estimated by the analyzer 110 exceeds the threshold Pₜₕ. If the correction controller 111 determines that output signal power does not exceed the threshold Pₜₕ, the correction controller 111 returns the processing to S100, at which the analyzer 110 analyzes the subsequent predetermined amount of the input digital audio signal.

The example in which the output signal power estimated does not exceed the threshold Pₜₕ corresponds to the first case described with reference to FIG. 2A. In this example, the excessive amount “error” is error=0, and the effect setting value and the gain setting value that have been used immediately before are used without change in the effect setting value generator 122 and the gain setting value generator 123. If it is immediately after when the user inputs an instruction of effect processing and gain controlling to the UI 121, effect processing and gain controlling instructed by the user are performed.

If the correction controller 111 determines that the output signal power exceeds the threshold Pₜₕ at S103, the correction controller 111 further determines whether it is the second case described with reference to FIG. 2B or the third case described with reference to FIG. 2C.

More specifically, if the correction controller 111 determines that it is the second case, that is, the output signal power does not exceed the threshold Pₜₕ through only the gain controlling by the gain setting value but does exceed the threshold Pₜₕ when, in addition to the gain controlling, the effect controlling by the effect setting value is performed (gain OK, effect NG), the correction controller 111 transfers the processing to S104.

If the correction controller 111 determines that it is the third case, that is, the output signal power exceeds the threshold Pₜₕ through only the gain controlling by the gain setting value and also exceeds the threshold Pₜₕ when the effect controlling by the effect setting value is performed (gain NG, effect NG), the correction controller 111 transfers the processing to S110.

The example in which the correction controller 111 determines that it is the second case at S103 and transfers the processing to S104 will be described first. At S104, the analyzer 110 detects the silence interval in a predetermined period T starting with the time point T₀ at which the output signal power is determined to exceed the threshold Pₜₕ, at S103. Any one of the first to the third methods described above may be used as the detection method of the silence interval. Here the first method is used to detect the silence interval. Furthermore, the number of silence intervals n has been detected in the period T.

At the subsequent S105, the correction controller 111 calculates the correction amount cur_error. For example, the correction controller 111 obtains the difference between the output signal power obtained at S102 and the threshold Pₜₕ as the excessive amount “error”. The correction controller 111 divides the excessive amount “error” by the number of the silence intervals n detected at S104 to calculate the correction amount cur_error.

After the processing proceeds to the subsequent S106, the correction controller 111 generates the correction value for the effect controlling to reduce the output signal power by the correction amount cur_error in the ith silence interval (i=1, 2, . . . , n). The silence interval where i=1, that is, the first silence interval refers to the temporally closest silence interval to the time point T₀. The correction controller 111 transfers the correction value to the effect setting value generator 122.

The effect setting value generator 122 generates the effect setting value based on the correction value transferred and sets the effect setting value on the effect controller 124. The effect controller 124 performs effect processing on the input digital audio signal in accordance with the effect setting value that has been set. As a result, the output signal power is reduced by the correction value cur_error compared with the state immediately before.

At the subsequent S107, the correction controller 111 determines whether correction processing on an n number of silence intervals has ended. If the correction controller 111 determines that the correction processing has not ended, the correction controller 111 returns the processing to S106 and performs correction processing on the subsequent silence intervals. If the correction controller 111 determines that the correction processing has ended, the correction controller 111 returns the processing to S100 and performs analysis processing on the subsequent predetermined amount of the input digital audio signal.

Next, the example in which the correction controller 111 determines that it is the third case at S103 and transfers the processing to S110 will now be described. At S110, in the same manner as S104 described above, the analyzer 110 detects the silence interval in the predetermined period T starting with the time point T₀ at which the output signal power is determined to exceed the threshold Pₜₕ at S103.

At the subsequent S111, the correction controller 111 determines whether priority of the sound quality is higher or priority of the power consumption reduction is higher. If the correction controller 111 determines that priority for the sound quality is higher, the correction controller 111 transfers the processing to S112. If the correction controller 111 determines that priority for the power consumption reduction is higher, the correction controller 111 transfers the processing to S120. The setting about whether priority is higher for sound quality or for power consumption reduction has been made in advance in the correction module 100. However, the embodiment is not limited to this example. The determination of whether the priority is higher for the sound quality or for the power consumption reduction may be input from the UI 121.

It is explained an example in which the correction controller 111 has determined that priority for the sound quality is higher, at S111. In this example, the entire excessive amount “error” is corrected only through gain controlling. Accordingly, the correction controller 111 calculates the correction amount cur_error for gain controlling at S112.

For example, the correction controller 111 obtains the maximum signal power added_max_gain[i] that satisfies Equation (10) below based on Equation (7) described above, and obtains the difference between the current signal power added_gain[i] and the signal power added_max_gain[i]. Then, by dividing the difference by the number of the silence interval n detected at S110, the value as the correction amount cur_error is obtained.

sig_spec_power[sig_max_index]+effected_gain[i]+added_max_gain[i]Pₜₕ (10)

After the processing proceeds to the subsequent S113, the correction controller 111 generates the correction value for gain controlling to reduce the output signal power by the correction amount cur_error in the ith silence interval. The correction controller 111 transfers the correction value generated to the gain setting value generator 123.

The gain setting value generator 123 generates the gain setting value based on the correction value transferred, and sets the gain setting value on the volume controller 125. The volume controller 125 performs gain processing on the input digital audio signal in accordance with the gain setting value that has been set. As a result, the output signal power is reduced by the correction value cur_error compared with the state immediately before.

At the subsequent S114, the correction controller 111 determines whether correction processing on the n number of silence intervals has ended. If the correction controller 111 determines that the correction processing has not ended, the correction controller 111 returns the processing to S113 and performs correction processing on the subsequent silence interval. If the correction controller 111 determines that the correction processing has ended, the correction controller 111 returns the processing to S100 and performs analysis processing on the subsequent predetermined amount of the input digital audio signal.

Next, an example in which the correction controller 111 has determined that priority for the power consumption reduction is higher is described. In this example, effect processing performed in the effect controller 124 is removed and the shortage of the output signal power is corrected through the gain controlling.

At S120, the correction controller 111 calculates the correction amount cur_error_eff for the effect controlling and the correction amount cur_error_pow for the gain controlling. For example, the correction controller 111 firstly obtains the output signal power P_{del}_{_{—}}_{eff} on which only effect is removed using Equation (11) below.

Pdel_eff=sig_spec_power[sig_max_index]+added_gain[i] (11)

The correction controller 111 assumes the obtained output signal power P_{del}_{_{—}}_{eff} as the threshold Pₜₕ (referred to as a assumed threshold Pₜₕ), and obtains the difference between the output signal power obtained at S102 and the assumed threshold Pₜₕ as the excessive amount error_eff. Then, by dividing the excessive amount error_eff by the n number of silence intervals calculated at S110, the correction amount cur_error_eff for effect controlling is obtained.

At S120, the correction controller 111 calculates the correction amount cur_error_pow for the gain controlling. For example, the correction controller 111 obtains the maximum signal power added_{—max}_gain[i] that satisfies Equation (12) below based on Equation (6) described above, and obtains the difference between the current signal power added_gain[i] and the signal power added_{—max}_gain[i]. Then, by dividing the difference by the n number of silence intervals detected at S110, the value as the correction amount cur_error_pow is obtained.

sig_spec_power[sig_max_index]+added_max_gain[]≦Pₜₕ (12)

When the correction amount cur_error_eff and the correction amount cur_error_pow are calculated at S120, the processing proceeds to S121. At S121, the correction controller 111 generates the correction value for the effect controlling to reduce the output signal power by the correction amount cur_error_eff in the ith (i=1, 2, . . . , n) silence interval in the same manner as S106 described above. The correction controller 111 transfers the correction value generated to the effect setting value generator 122.

The effect setting value generator 122 generates the effect setting value based on the correction value transferred, and sets the effect setting value on the effect controller 124. The effect controller 124 performs effect processing on the input digital audio signal in accordance with the effect setting value that has been set.

After the processing proceeds to the subsequent S122, the correction controller 111 generates the correction value for the gain controlling to reduce the output signal power by the correction amount cur_error_pow in the ith silence interval in the same manner as S113 described above. The correction controller 111 transfers the correction value generated to the gain setting value generator 123. The gain setting value generator 123 generates the gain setting value based on the correction value transferred and sets the gain setting value on the volume controller 125. The volume controller 125 performs gain processing on the input digital audio signal in accordance with the gain setting value that has been set.

The processing at S121 and S122 may be performed in parallel or in reverse order.

At the subsequent S123, the correction controller 111 determines whether the correction processing on the n number of silence intervals has ended. If the correction controller 111 determines that the correction processing has not ended, the correction controller 111 returns the processing to S121 and performs correction processing on the subsequent silence interval. If the correction controller 111 determines that the correction processing has ended, the correction controller 111 returns the processing to S100 and performs analysis processing on the subsequent predetermined amount of the input digital audio signal.

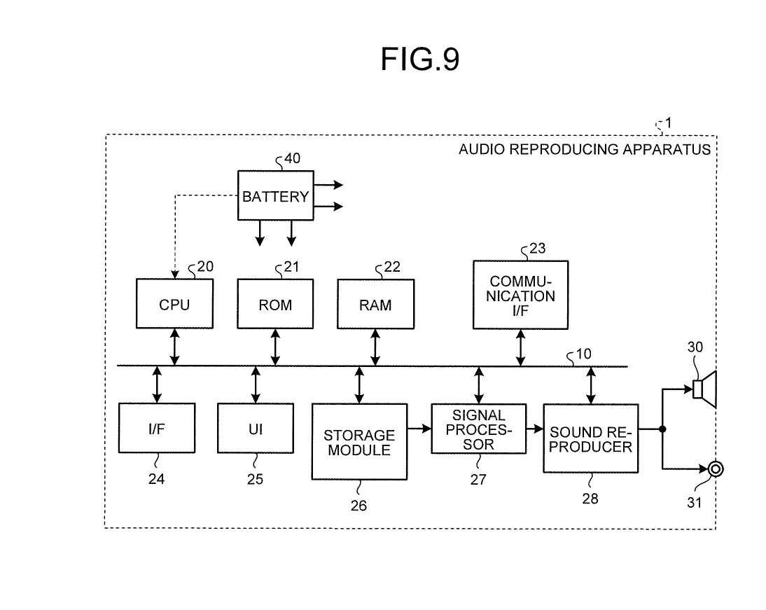

FIG. 9 illustrates an example of the structure of the audio reproducer to which the embodiment can be applied. As illustrated in FIG. 9, in the audio reproducer 1, a central processing unit (CPU) 20, a read only memory (ROM) 21, a random access memory (RAM) 22, and a communication interface (I/F) 23 are coupled to a bus 10. In addition, in the audio reproducer 1, an I/F 24, a UI 25, a storage module 26, a signal processor 27, and a sound reproducer 28 are coupled to the bus 10. A speaker 30 and an external output port 31 are coupled to the sound reproducer 28.

The CPU 20 uses the RAM 22 as a work memory in accordance with a program stored in advance in the ROM 21 to control entire operations of the audio reproducer 1. The functions of the correction module 100 described above can be achieved through the program running on the CPU 20, for example. The program achieving the functions of the correction module 100 on the CPU 20 is referred to as a sound processing program.

The communication I/F 23 controls wireless or wired communication with external devices or the like in accordance with instructions by the CPU 20. For example, the communication I/F 23 uses transmission control protocol/internet protocol (TCP/IP) as a communication protocol to be able to communicate with the external devices or the like through a local area network (LAN) or the Internet.

The I/F 24 controls the data communication between devices through wireless or wired communication in accordance with instructions by the CPU 20. As an example of the I/F 24, in regard to wired communication, a universal serial bus (USB) or institute of electrical and electronics engineers 1394 (IEEE1394) can be used. In regard to wireless communication, Bluetooth (registered trademark) can be used.

The UI 25 corresponds to the UI 121 illustrated in FIG. 1 and comprises an input module that receives a user input and a display module that presents information to users. For the UI 25, a so-called touch panel can be used that comprises in a single body a display module adopting a liquid crystal display (LCD) or an organic electro-luminescence (EL) display, for example, and an input module through which the display on the display module is penetrated and coordinate information corresponding to a pressed position is output. However, the embodiment is not limited to this example. The input module and the display module may be provided separately.

The storage module 26 is anon-volatile semiconductor memory, for example, and the digital audio signal is stored therein, for example. The storage module 26 may be provided removable from the audio reproducer 1 or may be embedded in the audio reproducer 1. If the storage module 26 is an embedded type storage, the digital audio signal is input from outside through the I/F 24 or the communication I/F 23 to be stored in the storage module 26.

The signal processor 27 comprises the effect controller 124 and the volume controller 125 illustrated in FIG. 1, and is configured of a digital signal processor (DSP), for example. The functions of the signal processor 27 may be achieved by the program running on the CPU 20. For example, the signal processor 27 inputs the digital audio signal that has been read out from the storage module 26 as the input digital audio signal and stores a predetermined amount thereof in the buffer memory once. Then, the signal processor 27 performs effect processing and gain controlling on the input digital audio signal that has been readout from the buffer memory in accordance with the effect setting value and the gain setting value and outputs the input digital audio signal. The buffer memory may be comprised in the signal processor 27 or may be achieved using the RAM 22.

The signal processor 27 may comprise the effect setting value generator 122 and the gain setting value generator 123 illustrated in FIG. 1. The effect setting value generator 122 and the gain setting value generator 123 may be comprised in the sound processing program described above.

The sound reproducer 28 corresponding to the sound reproducer 126 illustrated in FIG. 1 is, for example, a digital amplifier amplifying the amplitude of the digital audio signal that has been input to be integrated using a capacitor and then output as an analog audio signal capable of driving a speaker or a headphone. The sound reproducer 28 transmits information representing the output signal power corresponding to the output analog audio signal to the CPU 20.

The analog audio signal that has been output from the sound reproducer 28 is provided to the speaker 30, for example, and reproduced as a sound. The analog audio signal is also directed to the external output port 31. A headphone, for example, is coupled to the external output port 31.

The audio reproducer 1 is driven by a rechargeable battery 40. Information representing a remaining amount of battery power of the battery 40 is provided to the CPU 20.

As an example of the effect and gain control amount data storing module 120 illustrated in FIG. 1, a predetermined area of the storage module 26 can be used. Alternatively, the ROM 21 may be changed to a rewritable memory to record the effect and gain control amount data storing module 120 in a predetermined area thereof. The information 130 for analysis may also be stored in the ROM 21 or the storage module 26 in the same manner.

The sound processing program is not limited to be stored in advance in the ROM 21 and may be acquired separately. For example, the sound processing program may be acquired through an external network using the communication I/F 23. However, the embodiment is not limited to this example. The sound processing program may be acquired from a memory card in which the sound processing program is stored and that has been coupled to the I/F 24 in advance. The CPU 20 installs the sound processing program acquired on the ROM 21 in a predetermined procedure.

The sound processing program has a module structure comprising the modules (the analyzer 110 and the correction controller 111) constituting the correction module 100 described above, for example. The CPU 20 reads out the sound processing program from the ROM 21, for example, to be loaded into the RAM 22, so that the analyzer 110 and the correction controller 111 are formed on the RAM 22.

As described above, according to the audio processor in the embodiment, if the output signal power exceeds the threshold Pₜₕ, the silence interval is detected, in which the output signal power is reduced. Therefore, the output signal power can be changed in a manner that the user can hardly notice the change.

In the embodiment described above, although the output signal power is reduced based on power consumption, the embodiment is not limited to this example. For example, it is conceivable that the output signal power is reduced when an excessive output signal power is output continuously.

Specifically, in a portable audio reproducer, a headphone or an earphone is assumed to be used. When listening to sound at an excessive volume for a long time continuously, the user may suffer from damage to its auditory sense. In order to avoid the damage to the auditory sense, the reduction of the output signal power in the embodiment can be applied. In this case, it can be considered that the analyzer 110 analyzes the time in which the output signal power continues longer than a predetermined value. If the continued time analyzed exceeds a predetermined time, the silence interval is detected to suppress effect processing or gain controlling.

In the same manner, it is possible to enjoy advantageous effects in that the life of the speaker 30 is extended. In this case, the analyzer 110 analyzes the time in which the output signal power more than a predetermined value is output or the input digital audio signal to accumulate, for example, the frequency of a signal that can shorten the life of the speaker 30 such as a large volume of sound. It can be considered that, if the accumulated value exceeds a predetermined value, a silence interval is detected to suppress effect processing or gain controlling.

Moreover, the various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An audio processor comprising:
a detector configured to detect a first interval during which a state in which a reproduced sound by an audio signal is assumed to be silent continues for at least a first time; and
a controller configured to change, during the first interval, an output level of the audio signal.

2. The audio processor of claim 1, further comprising an effector configured to apply sound effect to the audio signal, wherein
the controller is configured to change the output level by controlling the effector.

3. The audio processor of claim 2, further comprising an analyzer configured to perform frequency analysis on the audio signal to obtain the signal level for each of frequency bands, wherein
the detector is configured to detect, as the first interval, an interval during which a state in which a signal level in at least one of the frequency bands is equal to or lower than a threshold continues for at least the first time, the effector applying the sound effect at the at least one of the frequency bands.

4. The audio processor of claim 1, wherein
the detector is configured to detect, as the first interval, an interval during which a state in which a signal level of the audio signal is equal to or lower than a threshold continues for at least the first time, and
the controller is configured to change the output level by controlling gain of the audio signal.

5. The audio processor of claim 1, wherein
the detector is configured to detect, as the first interval, an interval during which a state in which the reproduced sound is masked due to the temporal masking continues for at least the first time based on the signal level of the audio signal, and
the controller is configured to change the output level by controlling gain of the audio signal.

6. The audio processor of claim 4, wherein the first interval has a length in accordance with a predetermined frequency.

7. The audio processor of claim 3, wherein the first interval has a length in accordance with the at least one of the frequency bands at which the sound effect is applied.

8. A computer program product having a non-transitory computer readable medium including programmed instructions, wherein the instructions, when executed by a computer, cause the computer to perform:
detecting a first interval during which a state in which a reproduced sound by an audio signal is assumed to be silent continues for at least a first time; and,
during the first interval detected by the detecting, changing an output level of the audio signal.
